(19) United States
(12) Patent Application Publication
(10) Pub. No.: US 2025/0200256 A1
(43) Pub. Date: Jun. 19, 2025

(54) METHOD FOR IDENTIFYING AN AREA OF INTEREST, ASSOCIATED METHOD FOR EXPLORING A REGION OF INTEREST, SYSTEM AND COMPUTER PROGRAM PRODUCT

(71) Applicants: TotalEnergies OneTech, COURBEVOIE (FR); Centre national de la recherche scientifique, PARIS (FR); Université d'Aix-Marseille, MARSEILLE (FR)

(72) Inventors: Jeroen KENTER, Jurancon (FR); Alexandre LETTÉRON, PAU (FR); Jean BORGOMANO, Le Lauzet-Ubaye (FR); Yannick DONNADIEU, LA BASTIDONNE (FR); Alexandre POHL, GOURDON (FR)

(73) Assignees: TotalEnergies OneTech, COURBEVOIE (FR); Centre national de la recherche scientifique, PARIS (FR); Université d'Aix-Marseille, MARSEILLE (FR)

(21) Appl. No.: 18/846,801

(22) PCT Filed: Mar. 18, 2022
(86) PCT No.: PCT/IB2022/000140

§ 371 Date: Sep. 13, 2024

(51) Int. Cl. G06F 30/28

(52) U.S. Cl. CPC G06F 30/28

(57) ABSTRACT

The invention relates to a computer-implemented method for identifying at least one area of interest from a region of interest. The method comprises: obtaining a plurality of geo-information data over the region of interest for a geological time interval, the geo-information data comprising at least carbonate reference locations wherein marine carbonate sediments are observed, obtaining at least one paleo-digital elevation model of the region of interest, providing an Earth system model with a plurality of input sets of modeling parameters and obtaining output sets of paleoenvironmental parameters, determining a plurality of representative paleoenvironmental parameters for each carbonate reference location from the plurality of output sets of paleoenvironmental parameters, grouping at least a part of the carbonate reference locations into at least one group of carbonate reference locations defined as carbonate factory, and computing a susceptibility of occurrence of the carbonate factory.

### CROSS REFERENCE TO RELATED APPLICATIONS

The present application is a U.S. National Phase Application under 35 U.S.C. § 371 of International Patent Application No. PCT/IB2022/000140 filed Mar. 18, 2924. The entire contents of which are hereby incorporated by reference.

### FIELD OF THE INVENTION

The invention relates to a computer-implemented method for identifying at least one area of interest from a region of interest for exploration of water and non-renewable energy resources.

The non-renewable energy resources are for example oil and gas resources.

### BACKGROUND OF THE INVENTION

Current carbonate rock formations result from biological and/or abiotic processes which occurred during a time interval, under conditions determined primarily by environmental parameters such as light availability, water temperature, water salinity, nutrient concentration, biologically available oxygen and water chemistry.

A carbonate factory is defined by Schlager in “Carbonate Sedimentology and Sequence Stratigraphy”, SEPM Concepts in Sedimentology and Paleontology 8,199 p, 2005, as a subdivision of marine carbonate sediment production-systems based on the style of carbonate precipitation. This conceptual model includes a sediment-production window and rates associated to carbonate-production processes which are dependent of environmental conditions. This concept makes the link between 1) the hydrodynamic energy across a range of environmental conditions, 2) processes of carbonate sediment production which are commonly biotically induced (linked to organism assemblages), and 3) carbonate sediment-production ranges (carbonate production rates through bathymetric slope profiles). This concept was demonstrated in the present-day by Laugié et al. in “Global distribution of modern shallow-water marine carbonate factories: a spatial model based on environmental parameters”, Scientific Reports, 9, 2019, and in the past geological time by Michel et al. in “Marine carbonate factories: a global model of carbonate platform distribution, Int. J. Earth Sci. 108, 2019, or by Michel et al. in “Oligocene and Miocene Global Spatial Trends of Shallow-Marine Carbonate Architecture”, The Journal of Geology 128, 2020.

Due to their mineralogical properties and their sensitivity to dissolution, carbonate formations can present high porosity ranges which make them potential reservoirs. More than 60% of discovered reserves of oil and gas around the world are found in carbonate rock formations and the estimates for undiscovered reserves are in a similar range.

Several techniques have been developed in the past to identify potential exploration targets around the world in carbonate rock formations. 2D and 3D reflecting seismic imaging have been largely developed in the last decades, in terms of acquisition, processing and interpretation capabilities. However, these methods still have large uncertainties regarding the identification of carbonate rock presence and their intrinsic properties. Seismic interpretation is non-unique and the capability to successfully determine the presence of carbonates from common seismic attributes and reflectors is limited.

Other geophysical methods such as refraction seismic, gravity and magnetic methods allow improving the seismic interpretation, for example by allowing the distinction between some volcanic rocks and carbonates, but they are still insufficient in the search and the identification of carbonate rock formations that could represent effective hydrocarbon reservoirs.

### SUMMARY OF THE INVENTION

One aim of the invention is to provide an efficient and accurate method for identifying an area of interest from a region of interest to identify potential carbonate reservoirs.

To this aim, the subject-matter of the invention is a computer-implemented method for identifying at least one area of interest from a region of interest, in particular for exploration of water and/or non-renewable energy resources, the method being implemented by a system, the method comprising the following steps:
obtaining a plurality of geo-information data over the region of interest for a geological time interval, the geo-information data comprising at least carbonate reference locations wherein marine carbonate sediments are observed,
obtaining at least one paleo-digital elevation model of the region of interest for the geological time interval,
providing an Earth system model with a plurality of input sets of modeling parameters, each input set of modeling parameters comprising the at least one paleo-digital elevation model, an orbital configuration of the Earth, and an atmospheric carbon dioxide concentration value, the atmospheric carbon dioxide concentration value, or the paleo-digital elevation model being distinct to one input set of modeling parameters to another one, and, for each input set of modeling parameters, obtaining an output set of paleoenvironmental parameters as a function of spatial coordinates of the region of interest,
determining a plurality of representative paleoenvironmental parameters for each carbonate reference location from the plurality of output sets of paleoenvironmental parameters,
grouping at least a part of the carbonate reference locations into at least one group of carbonate reference locations based on similarities between at least a part of the representative paleoenvironmental parameters of said carbonate reference locations forming the controlling paleoenvironmental parameters, said controlling paleoenvironmental parameters being specific of a carbonate factory which produced marine carbonate sediments during the geological time interval,
computing a susceptibility of occurrence of the carbonate factory as a function of spatial coordinates of the region of interest using spatial distributions of the controlling paleoenvironmental parameters.

The method according to the invention may comprise one or more of the following features, taken solely or according to any potential technical combinations:
the representative paleoenvironmental parameter is a mean or a median value of the paleoenvironmental parameters of the output sets of paleoenvironmental parameters;
computing the susceptibility of occurrence of the carbonate factory comprises computing a susceptibility of occurrence for each of the controlling paleoenvironmental parameters;
the susceptibility of occurrence of the carbonate factory is obtained as a weighted sum of the susceptibility of occurrence of the controlling paleoenvironmental parameters;
the paleoenvironmental parameters comprise at least sea surface temperature and net primary productivity, and/or at least paleoenvironmental parameters obtained for summer season and paleoenvironmental parameters obtained for winter season;
the method further comprises computing a favorability of occurrence of the carbonate factory by thresholding the susceptibility of occurrence of the carbonate factory with a first threshold, the favorability of occurrence being equal to a first value for favorable locations of the region of interest wherein the susceptibility of occurrence is above the first threshold, and equal to a second value for unfavorable locations of the region of interest wherein the susceptibility of occurrence is below the first threshold, the first threshold being advantageously selected in a way that the favorability of occurrence of the carbonate reference locations of the group is equal to the first value;
the method comprises computing a probability of development of marine carbonates of the carbonate factory;
computing the probability of development comprises providing the paleo-climate model with a plurality of input sets of modeling parameters, the orbital configuration of the Earth being distinct to one input set of modeling parameters to another one;
computing the probability of development further comprises computing the susceptibility of occurrence of the carbonate factory for each one of said input sets of modeling parameters, and calculating the number of carbonate reference locations of the group for which the susceptibility of occurrence is above the first threshold;
the method further comprises determining a spatial confidence of the geo-information data over the region of interest, said spatial confidence being computed using at least two attributes among a marine carbonate presence attribute, a density attribute, a geo-information data-quality attribute and an age uncertainty attribute,

the marine carbonate presence attribute being representative of a presence of marine carbonate in a location of the region of interest, the density attribute being representative of a density of geo-information data in the location of region of interest, the geo-information quality attribute being representative of a quality of interpretation of the geo-information data when the geo-information is a well, an outcrop or a map in the location of the region of interest, the age uncertainty attribute being representative of a proportion of geo-information data in the location of the region of interest having at least a top age or a bottom age comprised in the geological time interval.
the method further comprises computing a first uncertainty relative to a location of a shallow water area using the paleo-digital elevation model and computing a second uncertainty relative to a presence of marine clastics in said shallow water area;
the method further comprises computing a spatial probability of presence of the carbonate factory using the susceptibility of occurrence, the first uncertainty and the second uncertainty;
the method further comprises computing a spatial probability of presence of the carbonate factory using the probability of development, the first uncertainty and the second uncertainty;
the method further comprises computing a statistical probability of presence of the carbonate factory over the region of interest, said statistical probability of presence being computed using a distance attribute representative to a distance between a location of the region of interest and one of the carbonate reference locations belonging to the group, and a density attribute representative of a density of said carbonate reference locations;
the method further comprises computing a global spatial favorability of presence of the carbonate factory by thresholding the spatial probability of presence, the statistical probability or a combination of the spatial probability of presence and of the statistical probability; and
the method further comprises assessing a thickness of the marine carbonate sediments of the group using thickness values measured in wells and/or outcrops, the global spatial favorability of presence and the spatial probability of presence.

The invention further relates to a method for exploring a region of interest for water and/or non-renewable energy resources, said method comprising:
identifying at least one area of interest from a region of interest using the method as disclosed above,
drilling said area of interest or carrying out a seismic survey on said area of interest.

The invention also relates to a system for identifying at least one area of interest from a region of interest, in particular for exploration of water and/or non-renewable energy resources, the system comprising:
a geo-information module configured to obtain a plurality of geo-information data over the region of interest for a geological time interval, the geo-information data comprising at least carbonate reference locations wherein marine carbonate sediments are observed,
an elevation module configured to obtain at least one paleo-digital elevation model of the region of interest for the geological time interval,
a modeling module configured to provide an Earth system model with a plurality of input sets of modeling parameters, each input set of modeling parameters comprising the at least one paleo-digital elevation model, an orbital configuration of the Earth, and an atmospheric carbon dioxide concentration value, the atmospheric carbon dioxide concentration value, or the paleo-digital elevation model being distinct to one input set of modeling parameters to another one, and, for each input set of modeling parameters, obtain an output set of paleoenvironmental parameters as a function of spatial coordinates of the region of interest,
a determining module configured to determine a plurality of representative paleoenvironmental parameters for each carbonate reference location from the plurality of output sets of paleoenvironmental parameters,
a grouping module configured to group at least a part of the carbonate reference locations into at least one group of carbonate reference locations based on similarities between at least a part of the representative paleoenvironmental parameters of said carbonate reference locations, said representative paleoenvironmental parameters being specific of a carbonate factory which produced the marine carbonate sediments during the geological time interval,
a computing module configured to compute a susceptibility of occurrence of a carbonate factory as a function of spatial coordinates of the region of interest using spatial distributions of the part of the representative paleoenvironmental parameters.

The invention relates to a computer program product comprising software instructions which, when the program is executed by a computer, cause the computer to carry out the method for identifying at least one area of interest from a region of interest, disclosed above.

### BRIEF DESCRIPTION OF THE DRAWINGS

The invention will be better understood, based on the following description, given solely as an example, and made in reference to the following drawings, in which:

FIG. 1 is a schematic view of a system according to the invention,

FIG. 2 is a flowchart of a method according to the invention, and

FIG. 3, FIG. 4, FIG. 5, FIG. 6, FIG. 7A, FIG. 7B and FIG. 8 are schematic flowcharts of some steps of the method of FIG. 2.

### DETAILED DESCRIPTION

The region of interest is preferably the world or a large part of the world such as an area comprising at least a part of a continent and at least a part of an ocean.

The geological time interval is typically a stratigraphic stage of several millions of years. For example, the geological time interval is the Burdigalian.

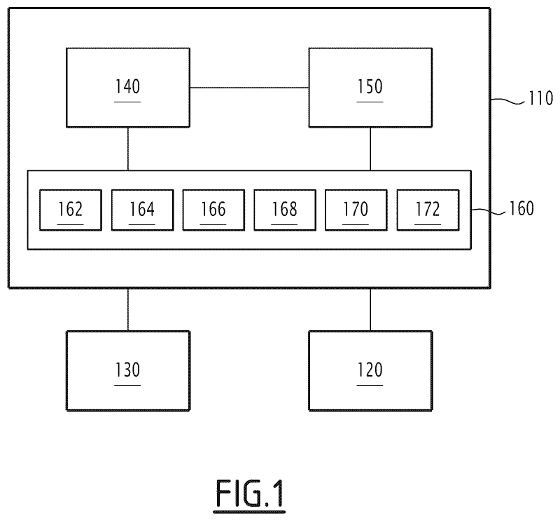

FIG. 1 is a schematic view of a system 100 according to the invention.

The system 100 comprises a calculator 110 for identifying at least one area of interest from a region of interest, a display unit 120 connected to the calculator 110 to display the results provided by the calculator and a man-machine interface 130.

The calculator 110 comprises a database 140. The database 140 contains for example the geo-information data that will be described further.

The database 140 is moreover able to store the results provided by the calculator 110.

In the example of FIG. 1, the database 140 is a local database comprised in the calculator 110. In a variant (not represented), the database 140 is a remote database connected to the calculator 110 by a network.

The calculator 110 comprises a processor 150 and a memory 160 receiving software modules. The processor 150 is able to execute the software modules received in the memory 160 to carry out the method according to the invention.

The memory contains a geo-information module 162, an elevation module 164, a modeling module 166, a determining module 168, a grouping module 170 and a computing module 172.

The memory may also contain any additional modules able to carry out any step or substep of the method that will described further.

The geo-information module 162 is configured to obtain a plurality of geo-information data over the region of interest for a geological time interval, the geo-information data comprising at least carbonate reference locations wherein marine carbonate sediments are observed.

The elevation module 164 is configured to obtain at least one paleo-digital elevation model of the region of interest for the geological time interval.

The modeling module 166 is configured to provide an Earth system model with a plurality of input sets of modeling parameters, each input set of modeling parameters comprising the at least one paleo-digital elevation model, an orbital configuration of the Earth, and an atmospheric carbon dioxide concentration value, the atmospheric carbon dioxide concentration value, or the paleo-digital elevation model being distinct to one input set of modeling parameters to another one, and, for each input set of modeling parameters, obtain an output set of paleoenvironmental parameters as a function of spatial coordinates of the region of interest.

The determining module 168 is configured to determine a plurality of representative paleoenvironmental parameters for each carbonate reference location from the plurality of output sets of paleoenvironmental parameters.

The grouping module 170 is configured to group at least a part of the carbonate reference locations into at least one group of carbonate reference locations based on similarities between at least a part of the representative paleoenvironmental parameters of said carbonate reference locations, said representative paleoenvironmental parameters being specific of a carbonate factory which produced the marine carbonate sediments during the geological time interval.

The computing module 172 is configured to compute a susceptibility of occurrence of a carbonate factory as a function of spatial coordinates of the region of interest using spatial distributions of the part of the representative paleoenvironmental parameters.

The display unit 120 is for example able to display the seismic images obtained with the method according to the invention. Moreover, the display unit 120 may display information relative to the progress of the method, such as the number of iterations, the lapsed time, etc.

Typically, the display unit 120 is a standard computer screen.

The man-machine interface 130 typically comprises a keyboard, a mouse and/or a touch screen to allow the user to activate the calculator 110 and the various software modules 162, 164, 166, 168, 170, 172 contained in the memory 160 to be processed by the processor 150, or any other modules configured to carry out a step or a substep of the method disclosed further.

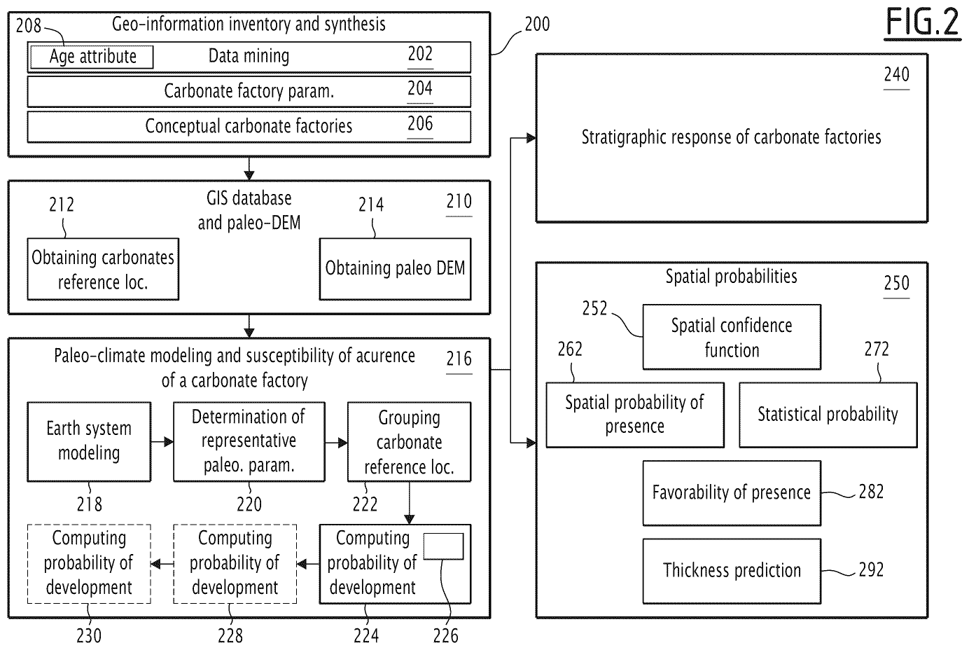

A flow chart of a computer-implemented method for identifying at least one area of interest from a region of interest, according to the invention, is shown in FIG. 2.

The method is carried by the system 100.

The method may comprise a step 200 of geo-information inventory and synthesis.

This step 200 comprises preferably a step 202 of data mining, sorting, extraction and homogenization, a step 204 of carbonate factory parametrization, and a step 206 of definition of conceptual carbonate factories.

In the step 202 of data mining, sorting, extraction and homogenization, an exhaustive inventory of available geo-information relative to the investigated geological time interval is made. The geo-information comprises a plurality of geo-information data. Each geo-information data has a location information such as location coordinates and an information relative to the time such as the bottom age and the top age. The location coordinates may be the present-day location or the palinspastic location, i.e., the location at the selected geological time interval.

For example, the geo-information data are at least one geochemical proxy such as the relative variation of the ratio ¹⁸O/¹⁶O (δ¹⁸O), the TEX₈₆ proxy based upon the distribution of archaeal membrane lipids, the ratio Mg/Ca, the clumped isotopes, geological formations and members, the gross thicknesses, the paleogeographic domain, the depositional environment, the depositional system, depositional rock types, the type of carbonate accumulation geometries, lithology, mineralogy, dominant lithofacies, non-skeletal components, paleontological skeletal components, sedimentary structures/bedding, (paleo)latitude, littoral configuration, paleoenvironmental parameters (e.g. light-based model, trophic regime, estimated water depth, estimated sea surface salinity and temperature, estimated nutrient dependence), basin types, tectonic plate types, tectonic regime, tectonic subsidence rate, platform types.

The geo-information data may be a value or an attribute.

For example, the attribute for the paleogeographic domain is chosen among continental, endogenous, shallow marine carbonate dominated, shallow marine clastic dominated, deep marine clastic dominated, etc.

For example, the attribute for the depositional environment is chosen between glacial, alluvial, lacustrine, coastal, pro-delta, carbonate lagoon, etc.

For example, the attribute for the depositional system is chosen among playa, erg, salina, reef, carbonate shoal, alluvial fan, tidal flat, etc.

For example, the attribute for the carbonate accumulation geometry is chosen among isolated platform, rimmed shelf, non-rimmed shelf, distally steepened ramp, homoclinal ramp, etc.

For example, the attribute for the lithology is chosen among limestone, conglomerate, siltstone, claystone, marls, etc.

For example, the attribute for the mineralogy is chosen among gypsum, anhydrite, dolomite, calcite, etc.

For example, the attribute for the dominant lithofacies is chosen among coralline algal floatstone to rudstone, large benthic foraminiferal rudstone, etc.

For example, the attribute for the non-skeletal components is chosen among peloids, ooids, oncoids, soft pebbles, spherulites, intraclasts, calcite rafts, chert, etc.

For example, the attribute for the paleontological skeletal component is chosen among phylum name, class name, order name, family name, genus name, etc.

For example, the attribute for the sedimentary structures/bedding is chosen among current ripples, trough cross-bending, wavy ripples, slumps, cross bedding, tangential bedding, parallel laminations, convolute laminations, bioturbation, etc.

For example, the attribute for the (paleo)latitude could be a value and/or is chosen among equatorial, tropical, subtropical, temperate, polar, etc.

For example, the attribute for the littoral configuration is chosen among restricted, open ocean, etc.

For example, the attribute for the light-based model is chosen among euphotic, mesophotic, oligophotic, aphotic, etc.

For example, the attribute for the trophic regime is chosen among dystrophic, eutrophic, mesotrophic, oligotrophic, ultra-oligotrophic, etc.

For example, the attribute for the basin type is chosen among rift related basin, foreland basin, foredeep basin, intracratonic basin, pull-apart basin, transpressional basin, strike slip basin, deep sea trench, inter-arc basin, fore-arc basin, back-arc basin, etc.

For example, the attribute for tectonic plate type is chosen among continental, transitional, oceanic.

For example, the attribute for tectonic regime is chosen among divergence, convergence, crustal flexure, transform motion, etc.

For example, the attribute for tectonic subsidence rate could be a value (expressed for example in m·Myr⁻¹) and/or chosen among high, low, medium, etc.

For example, the attribute for platform type is chosen among fault-block platform, salt-diapir platform, volcanic pedestal platform, thrust-top platform, foreland margin platform, delta-top platform, offshore bank or unattached platform, subsiding or passive margin platform, etc.

Preferably, at least some of the geo-information data are observations or measurements made on an outcrop and/or a sample from a drill hole and/or inside a drill hole. Preferably, some of the geo-information data are obtained by interpreting seismic data.

The sources of the geo-information data are a plurality of databases such as commercial, public domain, internal databases.

Preferably, the step 202 of data mining, sorting, extraction, and homogenization comprises a step 208 of associating an age attribute for each geo-information data. For example, the age attribute is chosen among the following group: “exact” for a geo-information data with a top and/or a bottom age referring the selected geological time interval or with an age within the selected geological time interval, and “centered” for a geo-information data with a top age younger than the top age of the selected geological time interval and a bottom age older than the bottom age of the selected geological time interval.

Preferably, the step 202 of data mining, sorting, extraction, and homogenization comprises a homogenization step to standardize the geo-information data extracted from the plurality of databases. For example, this step comprises grouping geo-information data using standardized attributes. Standardized attributes comprise for example the region names, the country names, the basin names, the lithologies, the paleogeographic domains, the depositional environments, the depositional systems, the basin types, styles of tectonics, etc.

Preferably, the step 202 of data mining, sorting, extraction and homogenization comprises sorting the geo-information data in a relational database and classifying extracted data from the geo-information data. Summary documents could be generated from extracted data and are for example at least a chronostratigraphic chart, i.e. a distribution of the geological formations through geological times sorted by location within region and/or country, images catalogs such as catalog of paleogeographic maps, catalog of depositional maps, catalog of carbonate accumulation geometries from seismic lines or cross-sections, system folders including original reference documents and thickness maps associated to location coordinates of available geo-information.

The step 204 of carbonate factory parametrization comprises identifying representative parameters among the geo-information data and/or the extracted data characterizing the carbonates factories. The representative parameters are for example the depositional models, geometries of carbonate accumulation, carbonate grain associations, associated lithological partitioning along the slope profiles, paleoenvironmental parameters, etc.

In the step 206 of definition of the conceptual carbonate factories, a coupling between the representative parameters is performed to define a list of conceptual carbonate factories. For example, Heterozoan (C-factory) marine carbonate production driven by organic matter presence and associated to heterotrophic biota recorded in the sedimentological record as transport-controlled prograding beds dominated by shell components, mostly developed on continental shelves under eutrophic oceanographic conditions in upwelling-influenced open-ocean platforms and/or with food supply from runoffs (Michel et al., 2019).

This conceptual carbonate factory scheme is used as labels to be transferred to previously edited maps and chronostratigraphic charts from step 202 and to consolidate data classification from step 204.

The method according to the invention comprises a step 210 of integration of the geo-information data into a geographic information system (GIS) geodatabase.

For example, the geo-information data are grouped in several data layers such as data points layers for well and outcrop locations, polyline layers for tectonic elements such as faults or 2D seismic lines, polygon layers for plate and basin boundaries for example or surface areas of 3D seismic blocks and raster layers for depositional maps for example.

The method comprises the selection of a world geodetic system including a coordinate system, a reference ellipsoid and a geoid. The method comprises the selection of a global Geodynamic Earth model. Then, the method comprises georeferencing the geo-information data in their palinspastic locations. In particular, the geo-information data with present-day location coordinates are rotated and translated to their corresponding palinspastic locations by using the selected global Geodynamic Earth model. Examples of such global Geodynamic Earth model are: PALEOMAP (Scotese and Wright, 2018, “PALEOMAP Paleodigital Elevation Models (PaleoDEMS) for the Phanerozoic PALEOMAP Project”), the Geognostics Earth Model (GEM™), PLATES (Lawver, L. A., Dalziel, I. W. D., Norton, I. O., Gahagan, L. M., and Davis, J. “The PLATES 2014 Atlas of Plate Reconstructions (550 Ma to Present Day), PLATES Progress Report No. 374-0215.” University of Texas Institute for Geophysics Technical Report No. 202 (February 2015), 220p.). For geo-information data already provided with a palinspastic location resulting from the use of a global Geodynamic Earth model distinct from the selected global Geodynamic Earth model, one option consists in applying a present-day restoration in present time by using the same global Geodynamic Earth model and then restoring the palinspastic location by using the selected global Geodynamic Earth model. Another option is to cut and subdivide maps into a plurality of sub-areas and apply a manual georeferencing by spatial adjustment based on the geographic information data already restored in their palinspastic locations (e.g., present-day country boundaries, cities, rivers).

This step of geo-referencing is important because, as described previously, paleo locations of some geographic information data are used as reference locations.

The step of integration of the geo-information data into a GIS geodatabase may preferably comprise a step of geo-parametrization. This step comprises a meshing of the region of interest by cells to form a grid. The cells are preferably squared and the meshing is uniform. Each cell has the same size, for example 2 km² or 10.000 km².

In a variant, the cell resolution can be refined in specific sub-areas of the region of interest to form several grids with different resolution. The region of interest is then composed of the merger of the different grids.

Step 210 comprises a step 212 of obtaining a plurality of carbonate reference locations wherein marine carbonate sediments are observed in the region of interest. The observations are for example made from outcrops and/or wells.

Preferably, the plurality of carbonate reference locations are in palinspastic locations. The carbonate reference locations are used as calibration points in the method according to the invention, as it will be explained further.

During step 212, preferably, each carbonate reference location, also referred as data point in the description, is associated with a plurality of geo-information data stored in the relational database such as a paleogeographic domain type, a depositional environment type and a depositional system type. The paleogeographic domain type, the depositional environment type and the depositional system type are typically defined by the standardized attributes defined in step 202. This information allows generating three new maps defined as the deep time calibrated paleographic domains map, the deep time calibrated depositional environments map and the deep time calibrated depositional systems map.

Each cell of the standardized paleographic domains map is associated with the dominant standardized paleographic domain observed in the wells and/or at the outcrops of the cell. In a similar way, each cell of the standardized depositional environments map and each cell of the standardized depositional systems map are respectively associated with the dominant depositional environment and the dominant depositional system observed in the wells and/or at the outcrops of the cell.

If there is a mismatch in a cell, a value of “undifferentiated” is associated to the cell.

Preferably, an age uncertainty map is also generated from the age attributes previously defined. For each cell of the age uncertainty map, a percentage of wells and/or outcrops featuring an age attribute equal to “exact” is calculated.

Contours of paleogeographic domains, depositional environments and/or depositional systems illustrated in existing gross depositional environment (GDE) maps are digitized and stored in the geodatabase. As for the data points, all generated surface areas are labelled in terms of standardized attributes of paleogeographic domain, depositional environment and depositional system. Three new maps are generated: paleogeographic domain contours, depositional domain contours, and depositional system contours.

Preferably, a step of palinspastic reconstruction and cell shaping of the three maps is performed to obtain three new maps: deep time paleogeographic domain contours, deep time depositional environment contours and deep time depositional system contours.

A new map called coverage and sources of mapped areas may be generated regarding the source and the coverage of available mapped areas. In said map, each cell overlapping mapped areas is identified by allocating the source(s) of intersecting map(s).

The previous maps: deep time calibrated paleogeographic domain map, deep time calibrated depositional environment map, deep time calibrated depositional system map, deep time paleogeographic domain contours map, deep time depositional domain contours map and deep time depositional system contours map are compiled together to form GCP reconstructed paleogeographic domain, GCP reconstructed depositional environment and GCP reconstructed depositional system. These layers are edited in the palinspastic system. These maps may be restored in the present-day positions and be referenced as GCP paleogeographic domains map, GCP depositional environment map and GCP depositional system map.

The method may comprise generating a constraint map for the paleo-digital elevation model. This map is elaborated based on the geo-information linked to each data point, especially, using the paleogeographic domain type, the depositional environment type and the depositional system type associated to each data point. The constraint map is built using a set of rules. For example, a rule compares the proportion of data points in a cell presenting a first predetermined attribute for the paleogeographic domain type and/or a first predetermined attribute for the depositional environment type and/or a first predetermined attribute for the depositional system and the proportion of data points in the cell presenting a second attribute for the paleogeographic domain type and/or a second attribute for the depositional environment type and/or a second attribute for the depositional system, the second attribute being distinct from the first attribute.

The rules detect the presence of at least one data point in a cell presenting a predetermined attribute for the paleogeographic domain type and/or the depositional environment type and/or the depositional system type.

Each rule applies at the cell scale.

Examples of rules are:
if the proportion of data points presenting the attribute “continental” is higher than the proportion of data points presenting the attribute “shallow marine carbonate”, the attribute for the cell of the constraint map is “coastal carbonate dominated environment”,
if the proportion data points presenting the attribute “continental” is higher than the proportion of data points presenting the attribute “shallow marine clastics”, the attribute for the cell of the constraint map is “coastal clastic dominated environment”,
if the proportion of data points presenting the attribute “shallow marine carbonate” is equal to the proportion of data points presenting the attribute “shallow marine clastics”, the attribute for the cell of the constraint map is “shallow marine carbonate clastic mixed environment”;
if the proportion of data points presenting the attribute “shallow marine carbonate” is higher than the proportion of data points presenting the attribute “shallow marine clastics”, the attribute for the cell of the constraint map is “shallow marine carbonate dominated environment”;
if the proportion of data points presenting the attribute “shallow marine clastic” is higher than the proportion of data points presenting the attribute “shallow marine carbonate”, the attribute for the cell is “shallow marine clastic dominated environment”;
if at least one data point in the cell has the attribute “salina” or “sabkha”, the attribute for the cell value of the constraint map is “evaporite-rich environments” even if other qualifiers are present;
if the proportion of data points presenting the attribute “shallow marine clastic” is higher than the proportion of data points presenting the attribute “deep marine environments”, the attribute for the cell of the constraint map is “shelf break clastic dominated transition”;
if the proportion of data points presenting the attribute “shallow marine carbonate” is higher than the proportion of data points presenting the attribute “deep marine environments”, the attribute for the cell of the constraint map is “shelf break carbonate dominated transition”;
if at least one data point in the cell presents the attributes “continental” and “deep marine”, the attribute for the cell is “continental marine sharp transition” even if other qualifiers are found;
if the proportion data points presenting the attribute “continental” is higher than the proportion of data points presenting the attribute “endogenous”, the attribute for the cell for the constraint map is “endogenous continental environment”;
if the proportion of data points presenting the attribute “shallow marine” or “deep marine” is higher than the proportion of data points presenting the attribute “endogenous”, the attribute for the constraint map is “endogenous marine environment”;
if the attributes of all the data points of a cell is “continental”, the attribute for the cell for the constraint map is “continental undifferentiated” or “lacustrine” or “fluvial” if available geo-information exists;
if at least one data point in the cell presents the attributes “salina” or “sabkha”, the attribute for the cell of the constraint map is “evaporite-rich environments” even if other qualifiers are present;
if the data points of a cell present the attributes “deep marine undifferentiated” and/or “deep marine carbonate dominated” and/or “deep marine clastic dominated”, the attribute for the cell of the constraint map is “deep marine environments”;
If at least one data point presents the attribute “absent”, the attribute for the cell of the constraint map is “absent deposits”.

Preferably, regarding the attributes “shallow marine carbonate dominated environments” and “shallow marine carbonate clastic mixed environment”, the relative weighting of data points per cell is scored using a scale of 1 (area including 1 calibration point) to 4 (include more than 4 calibration points).

Then, the method comprises a step 214 of obtaining at least one paleo-digital elevation model of the region of interest for the geological time interval.

For example, paleo topographic values from the PALEOMAP paleo-digital elevation model (Scotese and Wright, 2018) are extracted by applying a continental plate mask from the PALEOMAP-related Geodynamic Earth model. Raster values are extracted by GIS gridding following by an extraction of elevation values at each centered point of the cells. The paleo-location of elevation values are restored in present-day by using the PALEOMAP-related Geodynamic Earth model and then rotated in the selected geological time interval by using the predetermined Geodynamic Earth model. Missing paleo-bathymetric values are extracted by the same process from available deep marine paleo-depth reconstruction (e.g. Müller et al., 2008, “Long-Term Sea-Level Fluctuations Driven by Ocean Basin Dynamics”, Science, 319, pp. 1357-1362; Straume et al., 2020, “Global Cenozoic Paleobathymetry with a focus on the Northern Hemisphere Oceanic Gateways”, Gondwana Research 86, pp. 126-143). Raster values of both maps are concatenated to obtain a new paleo-digital elevation model consistent with the predetermined Geodynamic Earth model (e.g., GEM™). The resulting product is the paleo-digital elevation (PaleoDEM) base map. The paleo-elevation (i.e., paleo-topography and paleo-bathymetry) of the base map corresponds to the elevation ranges defined by Scotese, in “Tutorial: PALEOMAP PaleoAtlas for GPlates and the PaleoData Plotter Program”, 2016 or any other paleo-digital elevation model selected by the user.

Preferably, step 214 comprises a step for reconstructing paleo-bathymetry and paleo-topography. This step comprises a first sub step of data integration at global scale and base map edition, a second sub-step of reconstruction of an integrated paleo-digital elevation model and a third sub-step of edition of paleogeographic maps for the selected geological time interval.

In the first sub-step, the products of previous steps such as the present-day high-resolution elevation map and/or the available paleogeographic maps from both obtained in step 200 and/or the constraint map and/or the limit boundaries of the selected global tectonic plate model and terranes are integrated with the paleo-digital elevation base map using the selected global Geodynamic Earth model to obtain an integrated paleo-digital elevation map.

According to the uniformitarianism principle that present day observed relationships between elevation and plate tectonic environments also apply to the past (e.g., Whewell, 1837, “History of the inductive sciences, 3^{rd} edition, Parker, London, Vol. 3), the present-day elevation ranges are transposed to paleo-tectonic environments or physiographic terrains (e.g., anorogenic land, underplated collision zones, oceanic volcanic arc, obducted complexes) and associated present-day elevation ranges are used as paleo topographic proxies (e.g. Wells, M. R., 2008, “Tidal Modelling of modern and ancient seas and oceans” PhD Thesis, Imperial College London, 527p.). This step also involves the generation of a tectonic framework based on a literature search to identify subsidence or uplift of the site surfaces. Long-term variation of eustatic sea level (e.g., Haq, 1987, “Chronology of fluctuating sea level since the Triassic (250 million years ago to present), Science, 235, pp. 1156-1167; Abreu et al., 1998, “Oxygen isotope synthesis: a cretaceous ice-house? In Mesozoic and Cenozoic sequence stratigraphy of European basins, SEPM, Special Publication 60, 75-80) between the selected geological time interval and present-day is estimated (e.g., +200 m). The present-day lowland areas included in the eustatic delta range (e.g., 0 to +200 m) are then identified. A spectral analysis and image processing of the reconstructed high-resolution present-day global-scale elevation map (e.g., GEBCO Bathymetric Compilation Group, 2019. “The GEBCO_2019 Grid—a continuous terrain model of the global oceans and land”. British Oceanographic Data Centre, National Oceanography Centre, NERC, UK. doi:10/c33m. doi:10.5285/836f016a-33be-6ddc-e053-6c86abc0788e) is generated to highlight these potential coastal submerged areas if no vertical tectonic movements (uplift or subsidence) are inferred.

In the second sub-step, the integrated paleo-digital elevation map is corrected for deviations. For example, the integrated paleo-digital map is compared with the relative water depth indicators obtained as geo-information data in step 200 and corrected where deviations are observed to honor the geo-information data (e.g., paleobiology indicators as Cao et al., 2017, “Improving global paleogeography since the late Paleozoic using paleobiology”, Biogeosciences, 14, pp. 5425-5439).

Existing global paleogeographic maps (PALEOMAP—Scotese and Wright (2018), Deep Time Maps Inc.—Blakey (2008), “Gondwana paleogeography from assembly to breakup—a 500-million-year odyssey, in Resolving the Late Paleozoic Ice Age in Time and Space, Geological Society of America, Special paper 441, 1-28, DARIUS—Barrier et al. (2018) in “Paleotectonic Reconstruction of the Central Tethyan Realm”, Tectono-Sedimentary-Palinspastic maps from Late Permian to Pliocene, Kiessling et al (2003) in “Patterns of Phanerozoic carbonate platform sedimentation, LETHAIA, 36, 195-225, Golonka et al. (1994) in “Phanerozoic paleogeographic and paleoclimatic modeling maps, Pangea: Global environment and resources, Canadian Society of Petroleum Geologists Memoir, 17147; CGG—Merlin+, Halliburton—Neftex®, Getech) available for the selected geological time interval are used as both information support and quality control. Where major differences are observed, a specific regional investigation is executed.

The correction may also be made by taking into account elevations ranges derived from present-day tectonophysiographic terranes estimated for a specific tectonic and/or geodynamic setting (methods described in Markwick and Valdes, 2004, “Palaeo-digital elevation models for use as boundary conditions in coupled ocean-atmosphere GCM experiments: a Maastrichtian (late Cretaceous) example” Palaeogeography, Palaeoclimatology, Palaeoecology 213, pp. 37-63; Markwick, 2018, “Palaeogeography in exploration” Geol. Mag. pp. 1-42). Elevation values are preferably locally corrected to match the combination of all available paleo-altimetry proxies (e.g., fission track data, clumped isotope paleothermometry Δ₄₇) and associated methods (e.g., source to sink studies, flexural modeling, backstripping calculations, dynamic topography) to determine for instance tectonic uplifted areas.

The method may comprise generating a plurality of alternative corrected integrated paleo-digital elevation maps if there are uncertainties and/or low data coverage is observed (for example critical seaways or topographic highs).

The third sub-step comprises, from the corrected integrated paleo-digital elevation map(s), generating for example a paleo-shoreline map and/or the paleo-shelf break map, and/or map of shallow-water marine areas.

The paleo-shoreline map represents the limit between the oceans and the continents for the selected geological time interval.

The paleo-shelf break map represents the boundary between the outer shelf and the upper part of the continental slope that separates inshore waters from the open ocean for the selected geological time interval. A shelf break is characterized by markedly increased slope gradients toward the deep ocean bottom. Preferably, the shelf slope break is comprised between—10 m and—600 m water depth, for example—133 m water depth could be used as a mean value (Britannica, The Editors of Encyclopaedia. “shelf break”. Encyclopedia Britannica, 11 Mar. 2016, https://www.britannica.com/science/shelf-break. Accessed 26 Nov. 2021).

The shallow-water marine area represents the coastal zone within a shelf-break for the selected geological time interval.

Then, the method according to the invention comprises a step 216 of carbonate factory niche modeling.

This step comprises a step 218 of Earth system modeling with a plurality of input sets of modeling parameters, and, for each input set of modeling parameters, obtaining an output set of paleoenvironmental parameters as a function of spatial coordinates of the region of interest. The Earth system model seeks to simulate all relevant aspects of the Earth system including physical, chemical and biological processes by coupling ocean-atmosphere circulations with ocean biology and (biogeo)chemistry.

For example, the Earth system model is IPSL CM5A2 (Sepulchre et al. (2020) IPSL-CM5A2—an Earth system model designed for multi-millennial climate simulations. Geosci. Model Dev. 13, pp. 3011-3053. https://doi.org/10.5194/gmd-13-3011-2020) or MITgcm (Marshall et al. (1997) A finite-volume, incompressible Navier Stokes model for studies of the ocean on parallel computers. J. Geophys. Res. 102, 5753-5766. https://doi.org/10.1029/96JC02775); Adcroft et al. (2004) Implementation of an atmosphere-ocean general circulation model on the expanded spherical cube. Mon. Weather Rev. 132, 2845-2863. https://doi.org/10.1175/MWR2823.1).

The modeling parameters comprise at least the paleo-digital elevation model, an orbital configuration of the Earth, a solar luminosity value and an atmospheric carbon dioxide concentration value.

Preferably, the modeling parameters may comprise an initial polar and equatorial ocean surface temperature value and/or an ocean bottom initial temperature value and/or an initial ocean salinity value and/or soil and vegetation parameters.

The paleo-digital elevation model is preferably the corrected integrated paleo-digital elevation model obtained in step 214.

The orbital configuration is for example described by a set of Earth's orbital parameters such as eccentricity, obliquity, and precession.

The resulting paleoenvironmental parameters comprise for example a sea surface temperature (SST), a marine net primary productivity (NPP), a sea surface salinity (SSS), precipitations/evaporation, a runoff, a tidal regime, a paleo-current, a freshwater balance, marine alkalinity, ocean oxygen concentrations, ocean free sulfide (euxinia), ocean nutrient concentrations, ocean convective adjustments and/or mixed-layer depth etc.

The marine net primary productivity or production by phytoplankton fuels the marine food web. Net primary production provides the energy as food sources for all heterotrophic activity (Finkel (2014) Marine Net Primary Production. In: Freedman B. (eds) Global Environmental Change. Handbook of Global Environmental Pollution, vol 1. Springer, Dordrecht. https://doi.org/10.1007/978-94-007-5784-4_42).

Preferably, the paleoenvironmental parameters comprise at least parameters obtained for summer season and parameters obtained for winter season. It may also be a more complex combination of overlapping monthly data values.

According to the invention, the atmospheric carbon dioxide concentration value is distinct to one input set of modeling parameters to another one.

In other words, a sensitivity test for the atmospheric carbon dioxide concentration value is performed by running the Earth system model with the plurality of input sets of modeling parameters.

In a variant, the paleo-digital elevation model is distinct to one input set of modeling parameters to another one.

In other words, a sensitivity test for the paleo-digital elevation model is performed by running the Earth system model with the plurality of input sets of modeling parameters. The distinct paleo-digital elevation models are for example obtained in step 214 while testing several geological configurations.

In another variant, the plurality of input sets of modeling parameters is divided into a first plurality and a second plurality sets of modeling parameters. In the first plurality, the atmospheric carbon dioxide concentration value is distinct to one input set of modeling parameters to another one and the paleo-digital elevation model is the same for all the input set of modeling parameters. In the second plurality, the paleo-digital elevation model being distinct to one input set of modeling parameters to another one and the carbon dioxide concentration value is the same for all the input set of modeling parameters.

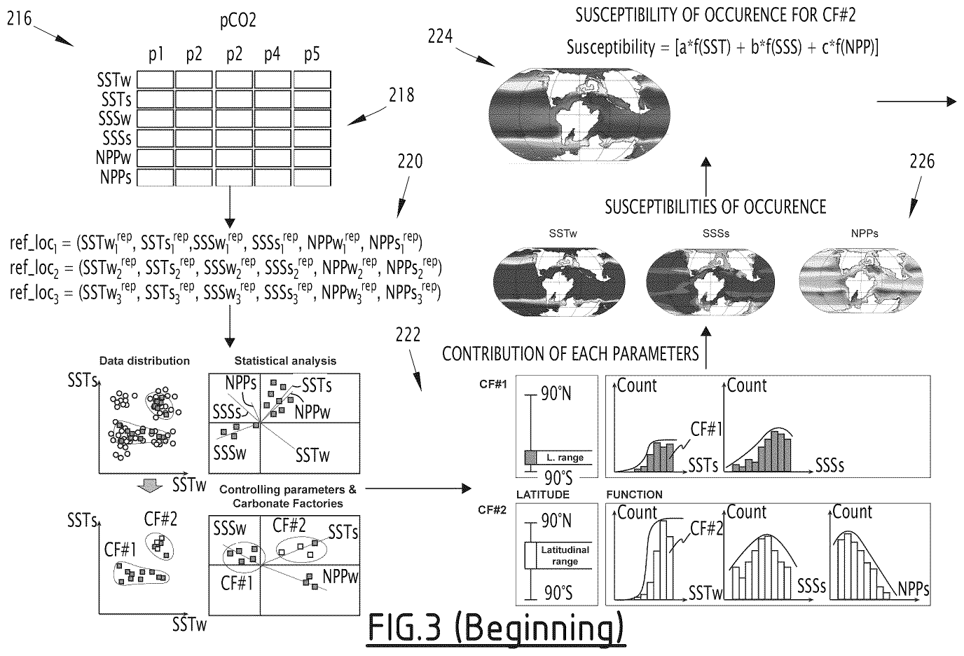

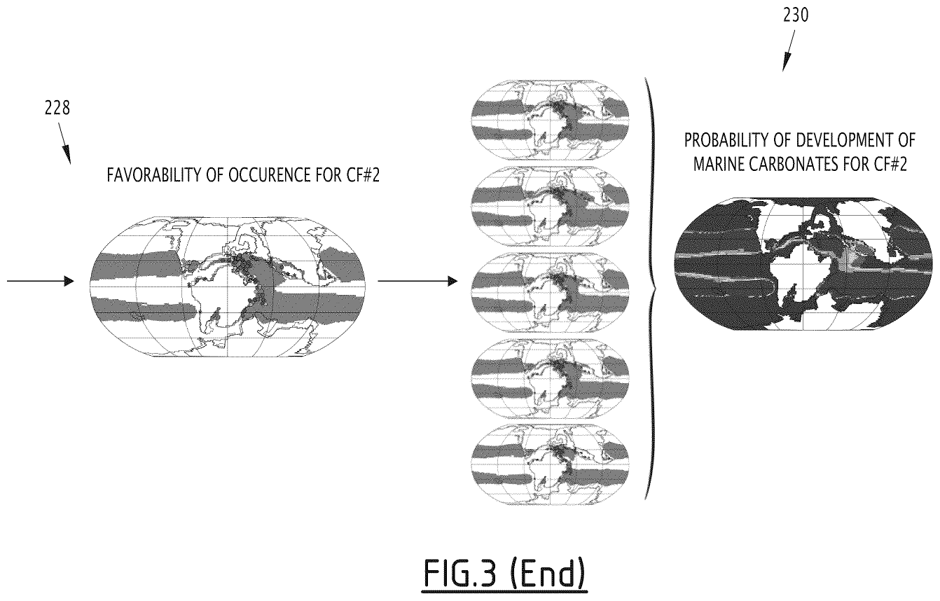

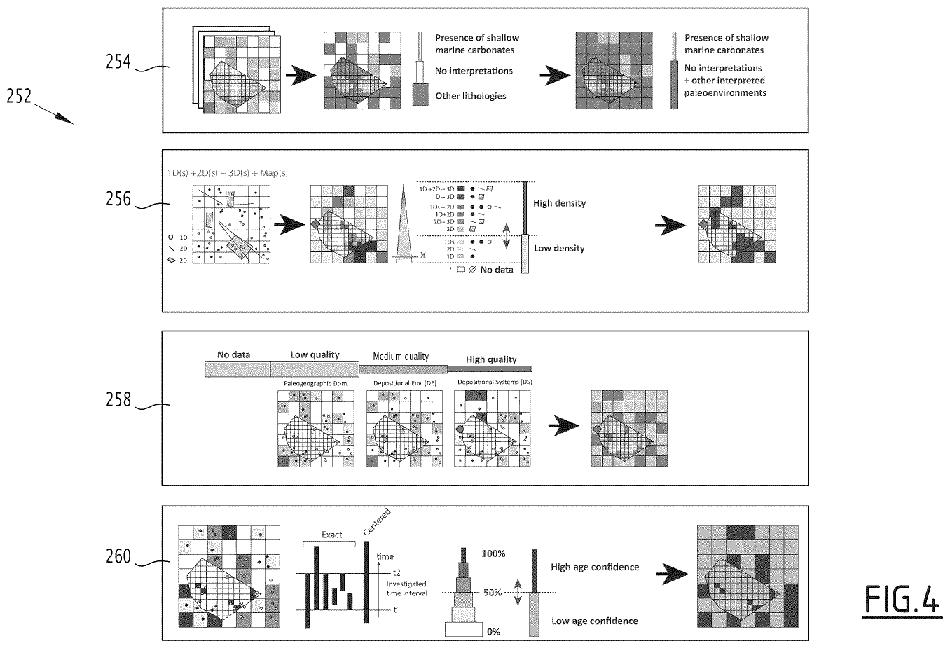

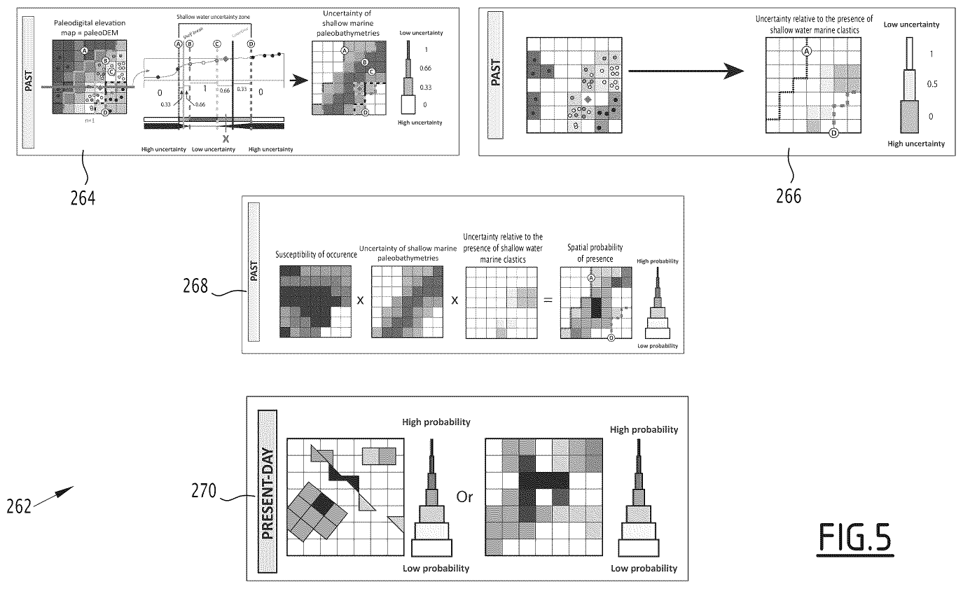

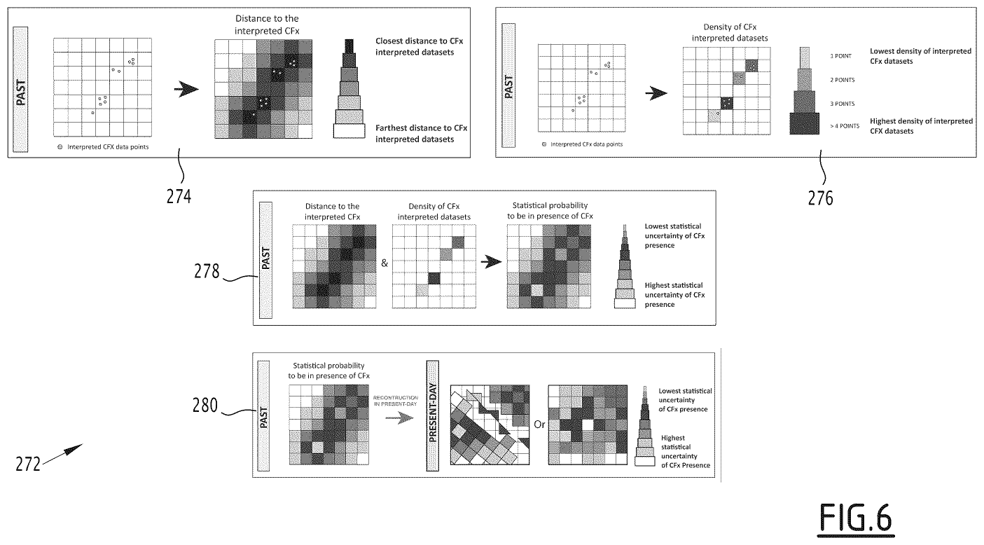

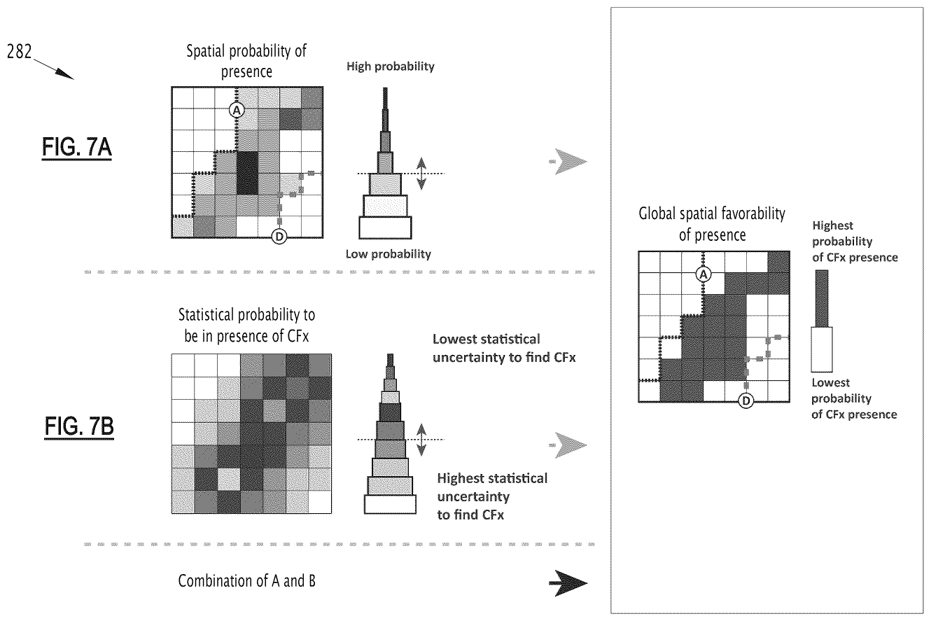

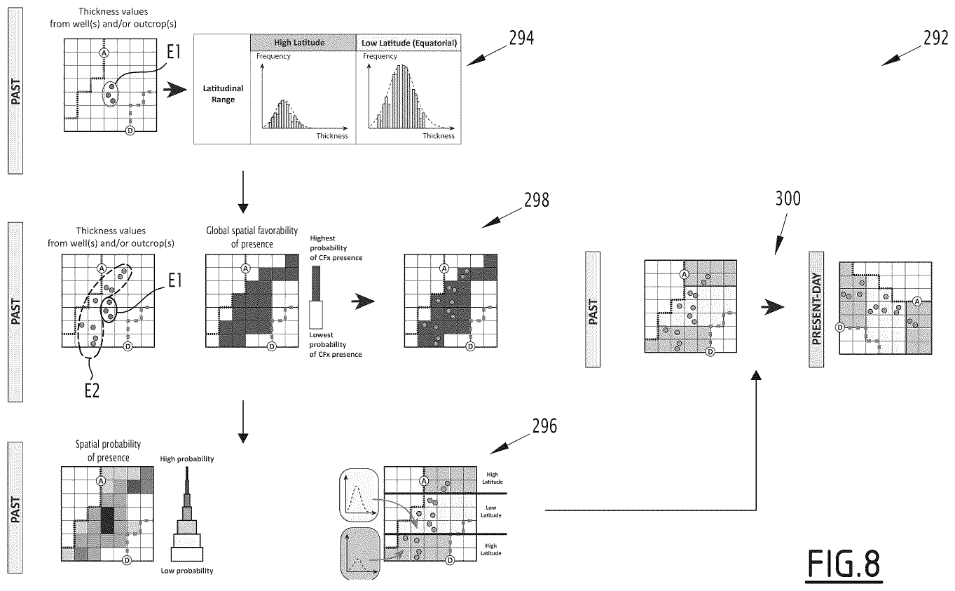

FIG. 3 presents a schematic example of the implementation of step 216. In this example, for the sake of simplicity, five input sets of modeling parameters with respectively a distinct atmospheric carbon dioxide concentration value equal to p1, p2, p3, p4 and p5 are successively provided to the Earth model system. Six paleoenvironmental parameters are computed for each input set of modelling parameters: the sea surface temperature for winter (SST_{w}) and for summer (SSTₛ), the sea surface salinity for winter (SSS_{w}) and for summer (SSSₛ), the marine net primary productivity for winter (NPP_{w}) and the marine net primary productivity for summer (NNPₛ).

Step 216 then comprises a step 220 for determining a plurality of representative paleoenvironmental parameters for each carbonate reference location from the plurality of output sets of paleoenvironmental parameters.

For example, the representative paleoenvironmental parameter is a mean value of the paleoenvironmental parameters of the output sets of paleoenvironmental parameters obtained with the plurality of input sets of modeling parameters.

In a variant, the representative paleoenvironmental parameter is a median value of the paleoenvironmental parameters of the output sets of paleoenvironmental parameters obtained with the plurality of input sets of modeling parameters.

In the example of FIG. 3, six representative paleoenvironmental parameters SST_{w}^{rep}, SSTₛ^{rep}, SSS_{w}^{rep}, SSSₛ^{rep}, NPP_{w}^{rep}, and NNPₛ^{rep} are computed respectively for the sea surface temperature for winter (SST_{w}) and for summer (SSTₛ), the sea surface salinity for winter (SSS_{w}) and for summer (SSSₛ), the marine net primary productivity for winter (NPP_{w}) and the marine net primary productivity for summer (NNPₛ).

The representative paleoenvironmental parameters are computed for any location of the region of interest and, in particular, for each carbonate reference location.

Therefore, for each carbonate reference location, a set of representative paleoenvironmental parameters is determined.

According to the invention, step 216 then comprises grouping 222 at least a part of the carbonate reference points into at least one group based on similarities between at least a part of the representative paleoceanographic parameters of said carbonate reference points. Each group is representative of a specific carbonate factory. Said carbonate factory produced the marine carbonate sediments observed at the reference locations of the group, during the geological time interval.

Preferably, several groups of carbonate reference points are determined. Each group is then representative of a carbonate factory.

To perform the grouping of the carbonate reference points, statistical techniques are used. The aim is to determine first order relationship trends between the representative paleoenvironmental parameters of the carbonate reference points. Methods are used to enhance relationships between the spatial distribution of the carbonate reference points and the representative paleoenvironmental parameters. Said methods are for example statistical stochastic and/or deterministic data analysis, such as principal component analysis, cluster analysis, fuzzy logic, nearest neighbor, etc.

A priori information may be used to perform the grouping of the carbonate reference points. The a priori information is for example the conceptual carbonate factories identified in step 206.

In the example of FIG. 3, two groups which are respectively representative of two carbonate factories CF #1 and CF #2 are determined.

Then, step 216 comprises computing 224 a susceptibility of occurrence of the/each group as a function of spatial coordinates of the region of interest using spatial distributions of the representative paleoenvironmental parameters of the group.

Preferably, this step 224 comprises computing 226 the susceptibility of occurrence of at least a part of the representative paleoenvironmental parameters of the group. During the grouping step, representative paleoenvironmental parameters controlling the group are identified.

In the example of FIG. 3 (step 222), for the first carbonate factory CF #1, the controlling representative paleoenvironmental parameters are the latitude, the sea surface temperature in summer and the sea surface salinity in summer. For the second carbonate factory CF #2, the controlling representative paleoenvironmental parameters are the latitude, the sea surface temperature in winter, the seas surface salinity in summer and the net primary productivity in summer.

FIG. 3 shows that the carbonate reference locations belonging to the second carbonate factory CF #2 have a rather high sea surface temperature in winter, an averaged sea surface salinity in summer and a rather low net primary productivity in summer.

The distribution of each controlling representative paleoenvironmental parameter is then turned into a normalized susceptibility of occurrence function (step 222). By applying the normalized susceptibility of occurrence function the representative paleoenvironmental parameters computed for any location of the region of interest, a susceptibility of occurrence is obtained as a function of spatial coordinates of the region of interest. In the example of FIG. 3, for the second carbonate factory CF #2, three maps of susceptibility of occurrence are obtained respectively for the sea surface temperature in winter, the seas surface salinity in summer and the net primary productivity in summer (step 226).

Preferably, the susceptibility of occurrence of the group is obtained as a weighted sum of the susceptibility of occurrence of each representative paleoenvironmental parameter of the group (step 224).

In other words, the susceptibility of occurrence of the group for the region of interest is computed with the following equation:

$${S}_{global} = \sum {a}_{i} \cdot {S}_{{paramter}_{i}}$$

S_{global} is the susceptibility of occurrence of the group over the region of interest.

Sₚₐᵣₐₘₑₜₑᵣ_{ᵢ} is the susceptibility of occurrence of the controlling representative paleoenvironmental parameter i of the group.

aᵢ is a weighting coefficient for the susceptibility of occurrence Sₚₐᵣₐₘₑₜₑᵣ_{ᵢ}.

A mask may be applied to the result to remove areas that are harmful to a carbonate factory, for example a mask located outside a water depth range and/or a spatial area associated to a terrigenous rich paleoenvironment and/or high marine salinity values unfavorable to the development of a specific carbonate factory.

In the example of FIG. 3, the susceptibility of occurrence of the group is computed as the following:

$${S}_{global} = {a}_{1} \cdot {S}_{{SST}_{w}} + {a}_{2} \cdot {S}_{{SSS}_{s}} + {a}_{3} \cdot {S}_{{NPP}_{s}}$$

The weighting coefficients are defined using an analytical process, which assigns higher weights to paleoenvironmental parameters that are expected to have a higher impact on the distribution of the carbonate factories.

Preferably, a threshold is applied on the susceptibility of occurrence to compute 228, a favorability map of occurrence to identify relevant spatial distribution of paleoenvironmental conditions favorable to develop the specific carbonate factory. The threshold is for example chosen based on the spatial distribution of the carbonate reference locations associated to the group in a way that the carbonate reference locations belonging to the group appear as favorable areas.

The favorability map is a binary map representing the favorable areas, wherein the paleoenvironmental conditions were favorable to develop the specific carbonate factory (susceptibility of occurrence above the threshold), and the non-favorable area (susceptibility of occurrence below the threshold).

Step 216 comprises computing 230 a probability of development of carbonates. This probability allows assessing the spatial uncertainty associated to the favorability map computed in step 228.

To compute the probability of development of carbonates, the Earth system model is provided with a plurality of input sets of modeling parameters. Each input set of modeling parameters comprises an orbital configuration of the Earth distinct from the orbital configuration of the Earth of the other input sets of modeling parameters.

Indeed, the previous computations made with the Earth system model for computing the susceptibility of occurrence are made with a median orbital configuration of the Earth which is very similar to the present day one. However, since the orbital configuration of the Earth for the selected geological time interval is not known, an important spatial uncertainty comes from the orbital configuration of the Earth.

In the example of FIG. 3, five input sets of modelling parameter are generated, each one having a different orbital configuration of the Earth.

Each input set of modelling parameter provides an output set of paleoenvironmental parameters as a function of spatial coordinates of the region of interest. For each output set of paleoenvironmental parameters, a map of susceptibility of occurrence of the group of carbonate sediments representative of the carbonate factory and a favorability map are computed using the same paleoenvironmental parameters, the same weighted sum of the susceptibilities of occurrence and the same threshold, as in steps 224 and 228.

Next, a favorability map for each input set of modeling parameters is obtained. The probability of development of carbonates is computed using the plurality of favorability maps. Locations wherein the favorability is positive for each favorability map represent locations wherein it is highly probable that the carbonates of the specific carbonate factory developed. On the contrary, locations wherein the favorability is null for each favorability map represent locations wherein it is highly probable that the carbonates of the specific carbonate factory did not develop.

The probability of development of marine carbonates allows highlighting the spatial areas wherein the results are the most robust.

The method according to the invention may further comprise a step 240 of computing a stratigraphic response of at least one of the carbonate factories using a forward stratigraphic model.

Forward stratigraphic modeling (FSM) allows predicting stratigraphy and facies architecture in an area through geological time, generally at basin or appraisal scale. Such kind of modeling is for example presented in EP 2 594 969 A1.

Different carbonate-process-based FSM software applications could be used, for example: Dionisos (Granjeon and Joseph (1999), “Concepts and applications of a 3D multiple lithology diffusive model in stratigraphic modeling”, in J. W. Harbaugh, W. L., Watney, E. C., Rankey, R. Slingerland, R. H. Goldstein and E. K. Franseen, eds., “Numerical experiments in stratigraphy recent advances in stratigraphic and sedimentologic computer simulation”: SEPM Special Publication, 62, pp. 197-210 or GPM Carbonates (e.g., Hill et al. (2009) Modeling shallow marine carbonate depositional systems. Computers & Geosciences 35 (9), pp. 1862-1874).

Forward stratigraphic modeling allows the testing of the stratigraphic response of carbonate factories in a constrained set of parameter ranges, including parameters such as the carbonate accumulation geometries (stratigraphic architecture), cumulative thickness and sediment type and distribution, of carbonate factories as a function of a limited set of parameters (e.g., initial paleotopography, eustacy, subsidence, carbonate production rates, water energy and sediment transport parameters, time step and total time experiment).

Typically, this step 240 is implemented in a sub-area of the region of interest wherein the susceptibility of occurrence is relatively high (favorable area) and wherein the quantity of geo-information is high. The objective is to estimate and to extract for each carbonate factory, rates of carbonate production along a bathymetric profile.

The selected sub-area is chosen among the areas having the most complete and reliable available geo-information based on step 200.

Forward stratigraphic models are generated with the objective to iteratively determine the optimal carbonate production profile along the shallow-water depositional profile. Once the carbonate production range is approximated, changes in accommodation space (sea level and subsidence) and transport rates are tested through hypothetical iterative modeling scenarios (sensitivity tests).

The resulting product is a depositional model, a resulting stratigraphic architecture and a calibrated carbonate productivity range associated to the sub-area and representative of a carbonate factory.

By running the methodology in a plurality of sub areas of the region of interest, the forward stratigraphic modeling results associated with a specific carbonate factory are combined to generate a catalog of two-dimension/three-dimension numerical facies grids acting as best constrained analogs. Ranges of the stratigraphic parameters: transport, subsidence and carbonate production rates of the best-constrained analogs are extracted and statistics of said parameters such as the minimum value, the maximum value and the mean value are computed.

The conceptual carbonate factories are then represented by two-dimensions sections illustrating the geometry of carbonate accumulations extracted from the best constrained models obtained by the forward stratigraphic modeling.

Finally, forward stratigraphic modeling using a combination of a subsidence regime rate and of an initial paleo-bathymetric slope profile are performed. For example, the subsidence regime rate is chosen among a low subsidence regime rate, a medium subsidence regime rate and a high subsidence regime rate. For example, the initial paleo-bathymetric slope profile is chosen among a ramp, a flat-topped or an isolated platform.

Preferably, forward stratigraphic modeling is performed for any combinations of a subsidence regime rate and of an initial paleo-bathymetric slope profile to build a matrix of possibility in term of resulting stratigraphic architecture associated to a specific carbonate factory.

The input modeling parameters for the forward stratigraphic modeling, e.g., the sea level change, the transport processes behavior and the carbonate production profile are considered as invariant. Preferably, the input modeling parameters are the stratigraphic parameters previously extracted.

Some of the combinations of a subsidence regime rate and of an initial paleo-bathymetric slope profile correspond to the best-constrained forward stratigraphic models previously modeled.

Each other combination leads to a conceptual forward stratigraphic model that can be used to compute for example a synthetic seismic image (e.g., Lanteaume et al. (2018) “Testing geologic assumptions and scenarios in carbonate exploration: Insights from integrated stratigraphic, diagenetic, and seismic forward modeling.” The leading edge, 37 (9), pp. 672-680).

The method according to the invention may comprise a step 250 for generating spatial probabilities associated with the presence of marine carbonates of a specific carbonate factory.

Step 250 may comprise a step 252 of assessing the global geo-information data confidence of interpreted marine carbonate systems in present-day positions. The step 252 determines a spatial confidence function that describes the variability in quality and space of the marine carbonate data used in the previous steps of the method.

Step 252 is explained in reference to FIG. 4.

Step 252 may comprise a sub-step 254 of determining marine carbonate dominated areas for the region of interest. This step 254 is made using the GCP paleogeographic domain map, the GCP depositional system map and the GCP depositional environment map obtained in step 210.

Each location of the region of interest, i.e., each cell of the region of interest, is classified into one of the two following categories: locations with a presence of marine carbonates (including marine carbonate-clastic mixed areas), locations with no available interpretation or with other interpreted paleo-environments excluding marine carbonates or marine carbonate-clastic mixed areas. The result is then a map representative of the presence of marine carbonates relative to the selected geological time interval in present-day position. Each cell of the map has a marine carbonate presence attribute chosen among a first attribute representative of the presence of marine carbonates or marine carbonate-clastic mixed areas and a second attribute representative of the absence of available interpretation or of the presence of other lithologies.

In a variant, a third category, with a third attribute, is used to discriminate cells with no available interpretation.

Step 252 may also comprise ranking 256 the region of interest based on the density of available geo-information data and the geo-information data type.

To perform this step, the present-day mapping of available geo-information data, including one-dimension geo-information data such as wells and outcrops, two-dimension geo-information data such as 2D seismic lines, and three-dimension geo-information data such 3D seismic surveys and GDE mapped areas are used to rank each cell in the region of interest.

For example, a cell including one well only has a lower value than a cell with one well and one outcrop. The definition of the ranking depends on the geo-information data availability.

For example, ten levels of density are defined, and each cell is classified into these levels of density. The first level, corresponding to the lower density, is given to the cells wherein there is no available geo-information data. Then, the second level is given to the cells including only one one-dimension geo-information data of a first type (e.g., well). The third level is given for cells including only one two-dimension geo-information data. The fourth level is given to cells including two one-dimension geo-information data of the first type and one one-dimension geo-information data of a second type (e.g., outcrop). The fifth level is given to cells including only one three-dimension geo-information data. The sixth level is given to cells including one three-dimension geo-information data and one two-dimension geo-information data. The seventh level is given to cells including one one-dimension geo-information data of the first type and one two-dimension geo-information data. The eighth level is given to cells including two one-dimension geo-information data of the first type, one one-dimension geo-information data of the second type and one two-dimension geo-information. The ninth level is given to cells including one one-dimension geo-information data of the first type and one three-dimension geo-information. The tenth level is given to cells including one one-dimension geo-information data of the first type, one two-dimension geo-information data and one three-dimension geo-information data.

Substep 256 may comprise applying a threshold on the level of density to split the region of interest between high-density areas wherein cells have a level of density higher than the threshold and low-density areas wherein cells have a level of density lower or equal to the threshold.

For example, going back to the example of FIG. 4, the threshold is fixed to the fourth level. Therefore, the cells having a level of density equal to the first level, the second level, the third level and the fourth level are classified as low-density cells and the cells having a level of density equal to the fifth level, the sixth level, the seventh level, the eighth level, the ninth level and the tenth level are classified as high-density cells.

The result is then a map representative of a low or a high density of geo-information data in the present day. Each cell of the map has a density attribute chosen among at least a first attribute representative of a low-density of geo-information data and a second attribute representative of a high-density of geo-information data.

Step 252 may also comprise evaluating 258 a geo-information data quality from wells and/or outcrops and/or GDE maps.

In this substep, the cells of the region of interest are classified into at least three categories. A low-quality level is given to cells wherein wells and/or outcrops and/or GDE maps do not provide any information regarding the paleogeographic domain, the depositional environment and the depositional system or cells wherein wells and/or outcrops and/or GDE maps provide only an information relative to the paleogeographic domain. A medium-quality level is given to cells wherein cells wherein wells and/or outcrops and/or GDE maps provide only an information relative to the paleogeographic domain and a low-quality level to cells wherein cells wherein wells and/or outcrops and/or GDE maps provide only an information relative to the depositional environment. A high-quality level is given to cells wherein cells wherein wells and/or outcrops and/or GDE maps provide an information relative to the paleogeographic domain, to the depositional environment and to the depositional system.

This substep 258 is preferentially performed using the GCP paleogeographic domains map, GCP depositional environments map and GCP depositional systems map obtained in step 210.

The result is then a map representative of the geo-information data quality from wells and/or outcrops and/or GDE maps. Each cell of the map has a geo-information data-quality attribute chosen among at least a first attribute representative of a low-quality, a second attribute representative of a medium-quality and a third attribute representative of a high-quality.

Step 252 may also comprise a substep 260 of age uncertainty assessment.

This substep 260 comprises classifying the cells according to their age uncertainty computed in step 210.

For example, the cells are classified into two categories. Then, a threshold is applied to the age uncertainty. The cells above the threshold are the cells including a relative high proportion of wells and outcrops with an age attribute equal to “exact”. The cells below the threshold are the cells including a relative low proportion of wells and/or outcrops with an age attribute equal to “exact”.

The result is then a map representative of the age uncertainty. Each cell of the map has an age uncertainty attribute chosen among at least a first attribute representative of a high-proportion of wells and outcrops with an age attribute equal to “exact” and a second attribute representative of low-proportion of wells and/or outcrops with an age attribute equal to “exact”.

The determination of the spatial confidence function is made by combining at least two attributes among the marine carbonate presence attribute, the density attribute, the geo-information data-quality attribute and the age uncertainty attribute.

Preferably, the fourth attributes are combined to determine the spatial data confidence function for marine carbonate environments of the region of interest. The spatial data confidence function is time dependent as loss of available datasets and associated understanding of geological systems through deep geological time thereby increases uncertainty. The result is for example a map which contains at least twelve outcomes. The ranking of the outcomes depends on the user.

Step 250 may comprise a step 262 for estimating a spatial probability of a presence of a specific carbonate factory at global scale using the susceptibility of occurrence of the group of marine carbonate sediments representative of the carbonate factory computed in step 224 or the probability of development computed in step 230.

Step 262 is described in reference to FIG. 5.

First, step 262 comprises a substep 264 for evaluating an uncertainty of shallow marine paleo-bathymetry. In particular, the uncertainty of the shallow water areas defined in step 214 as spatial regions between the coastline and the continental shelf break locations.

The uncertainty around the spatial extent of shallow water bathymetry is associated with the accuracy of both coastline and shelf break locations. The uncertainty around the shelf break position is delineated by the “maximal extension of the shelf break” in a seaward direction (dashed line labeled A in FIG. 5) toward the position of the nearest calibrated deep marine paleo-environment and its bathymetry and, by the “minimal extension of the shelf break” (dashed line labeled B in FIG. 5, closest to the shore) according to the deepest bathymetric value of the shallow-water marine interpreted paleo-environment.

The “maximal extension of the coastline” in a seaward direction (dashed line in FIG. 5 labeled C) is determined by the shallowest bathymetric value of the shallow marine interpreted paleo-environment and the bathymetric digital elevation. The “minimal extension of the coastline” (dashed line in FIG. 5 labeled D), closest to the onshore area, is defined by strictly delineating the extension of interpreted continental paleo-environments.

The result is a map with four new categories, representing uncertainty levels, from high (“0”) to low (“1”), as associated with the presence of shallow water paleo-environments and are used to modify the probability for carbonate presence in the form of multipliers. These categories are for example described and labelled as follows:
1) cells in areas between the shelf break at −200 m (continuous line in FIG. 5) and line A have an uncertainty attribute equal to 0.33,
2) cells in areas between the shelf break at −200 m and line B have an uncertainty attribute equal to 0.66,
3) cells in areas between the coastline and line D have an uncertainty attribute equal to 0.33 and,
4) cells in areas between the coastline and line C have an uncertainty attribute equal to 0.6.

Step 262 further comprises a substep 266 for assigning an uncertainty addressing the presence of shallow-water marine clastics in the shallow-water region as defined in the previous step.

The uncertainty is extracted from the constraint map generated in step 210.

Each cell has for example an uncertainty attribute chosen among a first attribute representative of a shallow water marine clastic dominated environment with a corresponding uncertainty equal to 0, a second attribute representative of a shallow-water marine carbonate-clastic mixed environment with a corresponding uncertainty equal to 0.5, and a third attribute representative of no shallow marine clastic paleo-environments with a corresponding uncertainty equal to 1.

In a substep 268, the uncertainty of shallow-water marine paleo-bathymetry obtained in substep 264 and the uncertainty relative to the presence of shallow water marine clastics obtained in substep 266 are combined with the susceptibility of occurrence computed in step 224 or with the probability of development computed in step 230 as probability multipliers into a global probability function for one specific carbonate factory to obtain a spatial probability of presence of the specific carbonate factory.

The result is a map showing the distribution of the predicted marine areas for a specific carbonate factory including the spatial uncertainty of marine paleo-bathymetric determinations and presence of marine clastics that will negatively affect through water turbidity the development of marine carbonate system.

Finally, step 262 may comprise converting 270 the spatial probability of presence of the specific carbonate factory obtained in palinspastic position to present-day position.

Typically, squared cells are distorted or cut according to the technic plate model used. To mitigate such distortions, centered values may be reconstructed rather than square surfaces. Reconstructed present-day positions of centered values are then assigned to an updated meshed grid as shown in FIG. 5.

Step 250 may also comprise a step 272 for assessing the data confidence associated to the carbonate reference locations interpreted as belonging to the group representative of the carbonate factory.

Step 272 is described in reference to FIG. 6.

In a first substep 274, each cell of the region of interest is given a distance attribute representative of a distance to a carbonate reference location interpreted as belonging to the group representative of the carbonate factory as shown in FIG. 6.

In a second substep 276, each cell of the region of interest is also given a density attribute representative of a density of carbonate reference locations interpreted as belonging to the group representative of the carbonate factory located in the cell.

The distance attribute and the density attribute are then combined to assess a statistical probability to be in presence of the carbonate factory in a third substep 278.

In a similar way as in step 262, step 272 may comprise a fourth substep 280 to convert the statistical probability to be in presence of the carbonate factory obtained in palinspastic position to present-day position.

In a final step 282 (FIG. 7A and FIG. 7B), the spatial probability of presence obtained in substep 268, the statistical probability to be in proximity of the carbonate factory obtained in substep 278, or a combination thereof are thresholded with a predetermined threshold to obtain a global spatial favorability of presence of the specific carbonate factory. Cells of the region of interest having a value above the predetermined threshold correspond to areas with a high probability of presence of the specific carbonate factory. Cells of the region of interest having a value below the predetermined threshold correspond to areas with a low probability of presence of the specific carbonate factory.

Finally, in a similar way as in steps 262 and 272, step 282 may comprise converting the spatial favorability of presence of the specific carbonate factory obtained in palinspastic position to present-day position.

Step 250 may also comprise a step 292 for determining a thickness of marine carbonate sediments associated to the specific carbonate factory over the region of interest.

Step 292 comprises a substep 294 for determining, for the specific carbonate factory, thickness frequency distributions for at least one parameter influencing spatial thickness distribution.

Thickness values come from observations E1 in wells and/or outcrops and/or seismic interpretations after time-to-depth conversion. The thickness frequency distributions of one or more carbonate factories (CFx) are determined for a number of user-defined spatial parameters influencing spatial thickness distributions. Spatial parameters are independent from CFx and utilized to distribute thickness in cells with a CFx probability greater than “0”.

The spatial parameter is for example chosen among the paleo-latitudinal position, basin type, tectonic plate type, tectonic regime, tectonic subsidence rate, platform type, paleogeographic domain type.

In the example of FIG. 8, the parameter identified as influencing the spatial thickness distribution for one carbonate factory is the paleo-latitudinal position. Two categories of paleo-latitudinal ranges are established: a low-latitude (equatorial) category and a high-latitude category. Thickness values can be labelled by carbonate factory type if the statistical relationship with the independent spatial parameter is meaningful. In such case.

The thickness frequency distributions are extracted from CFx data points associated for each user-defined combination, fitted by an appropriate distribution function (e.g., symmetric bells-shaped, skewed) and scaled to the total number of cells available within each of the latitudinal group combinations (substep 294). Finally, thickness is populated by CFx spatial probability and user-defined category (i.e., tectonic regime, latitude) for each cell by random draw (without replacement) from the associated normalized distribution in all cells with a CFx spatial probability greater than “0” (substep 296).

In case the number of thickness values by carbonate factory in one of the above-mentioned categories is statistically not acceptable, in substep 298, the number of thicknesses in the distribution of the category can be improved by including thicknesses E2 from those cells that have a spatial favorability of presence of the specific carbonate factory, obtained in step 282, greater than a predetermined threshold, for example greater than 0.5 (substep 298).

Note that this “boosting” step is depending on the quality and distribution/density of carbonate factory data points as well as the nature of the relationship, for example, with tectonic regime or latitude and therefore largely user-defined provided that there is a statistically meaningful relationship with the independent parameter.

In case a meaningful statistical relationship between one or more carbonate factories and spatial parameters is absent, a gross carbonate thickness relationship with spatial parameters can be investigated. In that case the following steps described above are followed in order to complete the population of thickness values in all shallow-water carbonate cells with a probability greater than “0”. The cell-based information on CFx (or gross shallow-water carbonate) and thickness is utilized to generate gross volume of accumulated carbonate for different statistical scenarios (i.e., P10, P50, P90).

In case, no statistical meaningful relationship is identified between thickness and a spatial parameter, an alternative statistical technique such as kriging or variogram statistics can be used.

In a similar way as in step 270, step 292 may comprise a fourth substep 300 to convert the predicted CFx-related thicknesses in palinspastic position to present-day position.

A method for determining at least a sub-region of the region of interest for exploration of water and non-renewable energy resources associated with carbonate systems will now be disclosed.

The method comprises first a step of selection of a region of interest and of a geological time interval.

The region of interest is preferably the world or a large part of the world such as an area comprising at least a part of a continent and at least a part of an ocean.

The geological time interval is typically a stratigraphic stage of several millions of years. For example, the geological time interval is the Burdigalian.

Then, the method comprises identifying at least one area of interest from a region of interest using the method.

The identification is made based on the susceptibility of occurrence and/or the favorability of occurrence and/or the probability of development and/or the spatial probability of presence and/or the statistical probability and/or the global spatial favorability of presence.

The area of interest corresponds to a relative high value of the above-mentioned quantities.

Then, the method comprises drilling said area of interest or carrying out a seismic survey on said area for exploration of water and/or non-renewable energy resources.

The technologies for drilling and for carrying out the seismic survey are well known and will not be detailed here.

1. A computer-implemented method for identifying at least one area of interest from a region of interest, the method being implemented by a system, the method comprising the following steps:
obtaining a plurality of geo-information data over the region of interest for a geological time interval, the geo-information data comprising at least carbonate reference locations wherein marine carbonate sediments are observed,
obtaining at least one paleo-digital elevation model of the region of interest for the geological time interval,
providing an Earth system model with a plurality of input sets of modeling parameters, each input set of modeling parameters comprising the at least one paleo-digital elevation model, an orbital configuration of the Earth, and an atmospheric carbon dioxide concentration value, the atmospheric carbon dioxide concentration value, or the paleo-digital elevation model being distinct to one input set of modeling parameters to another one, and, for each input set of modeling parameters, obtaining an output set of paleoenvironmental parameters as a function of spatial coordinates of the region of interest,
determining a plurality of representative paleoenvironmental parameters for each carbonate reference location from the plurality of output sets of paleoenvironmental parameters,
grouping at least a part of the carbonate reference locations into at least one group of carbonate reference locations based on similarities between at least a part of the representative paleoenvironmental parameters of said carbonate reference locations forming the controlling paleoenvironmental parameters, said controlling paleoenvironmental parameters being specific of a carbonate factory which produced marine carbonate sediments during the geological time interval, and
computing a susceptibility of occurrence of the carbonate factory as a function of spatial coordinates of the region of interest using spatial distributions of the controlling paleoenvironmental parameters.

2. The method according to claim 1, wherein the representative paleoenvironmental parameter is a mean or a median value of the paleoenvironmental parameters of the output sets of paleoenvironmental parameters.

3. The method according to claim 1, wherein computing the susceptibility of occurrence of the carbonate factory comprises computing a susceptibility of occurrence for each of the controlling paleoenvironmental parameters.

4. The method according to claim 1, wherein the susceptibility of occurrence of the carbonate factory is obtained as a weighted sum of the susceptibility of occurrence of the controlling paleoenvironmental parameters.

5. The method according to claim 1, wherein the paleoenvironmental parameters comprise at least sea surface temperature and net primary productivity, or at least paleoenvironmental parameters obtained for summer season and paleoenvironmental parameters obtained for winter season.

6. The method according to claim 1, further comprising computing a favorability of occurrence of the carbonate factory by thresholding the susceptibility of occurrence of the carbonate factory with a first threshold, the favorability of occurrence being equal to a first value for favorable locations of the region of interest wherein the susceptibility of occurrence is above the first threshold, and equal to a second value for unfavorable locations of the region of interest wherein the susceptibility of occurrence is below the first threshold, the first threshold being advantageously selected in a way that the favorability of occurrence of the carbonate reference locations of the group is equal to the first value.

7. The method according to claim 6, comprising computing a probability of development of marine carbonates of the carbonate factory.

8. The method according to claim 7, wherein computing the probability of development comprises providing the paleo-climate model with a plurality of input sets of modeling parameters, the orbital configuration of the Earth being distinct to one input set of modeling parameters to another one.

9. The method according to claim 8, wherein computing the probability of development further comprises computing the susceptibility of occurrence of the carbonate factory for each one of said input sets of modeling parameters, and calculating the number of carbonate reference locations of the group for which the susceptibility of occurrence is above the first threshold.

10. The method according to claim 1, further comprising determining a spatial confidence of the geo-information data over the region of interest, said spatial confidence being computed using at least two attributes among a marine carbonate presence attribute, a density attribute, a geo-information data-quality attribute and an age uncertainty attribute,
the marine carbonate presence attribute being representative of a presence of marine carbonate in a location of the region of interest, the density attribute being representative of a density of geo-information data in the location of region of interest, the geo-information quality attribute being representative of a quality of interpretation of the geo-information data when the geo-information is a well, an outcrop or a map in the location of the region of interest, the age uncertainty attribute being representative of a proportion of geo-information data in the location of the region of interest having at least a top age or a bottom age comprised in the geological time interval.

11. The method according to claim 1, further comprising computing a first uncertainty relative to a location of a shallow water area using the paleo-digital elevation model and computing a second uncertainty relative to a presence of marine clastics in said shallow water area.

12. The method according to claim 11, further comprising computing a spatial probability of presence of the carbonate factory using the susceptibility of occurrence, the first uncertainty and the second uncertainty.

13. The method according to claim 11, further comprising computing a spatial probability of presence of the carbonate factory using the probability of development, the first uncertainty and the second uncertainty.

14. The method according to claim 12, further comprising computing a statistical probability of presence of the carbonate factory over the region of interest, said statistical probability of presence being computed using a distance attribute representative to a distance between a location of the region of interest and one of the carbonate reference locations belonging to the group, and a density attribute representative of a density of said carbonate reference locations.

15. The method according to claim 14, further comprising computing a global spatial favorability of presence of the carbonate factory by thresholding the spatial probability of presence, the statistical probability or a combination of the spatial probability of presence and of the statistical probability.

16. The method according to claim 15, further comprising assessing a thickness of the marine carbonate sediments of the group using thickness values measured in wells or outcrops, the global spatial favorability of presence and the spatial probability of presence.

17. A method for exploring a region of interest for water or non-renewable energy resources, said method comprising:
identifying at least one area of interest from a region of interest using the method according to claim 1,
drilling said area of interest or carrying out a seismic survey on said area of interest.

18. A system for identifying at least one area of interest from a region of interest, the system comprising:
a geo-information module configured to obtain a plurality of geo-information data over the region of interest for a geological time interval, the geo-information data comprising at least carbonate reference locations wherein marine carbonate sediments are observed,
an elevation module configured to obtain at least one paleo-digital elevation model of the region of interest for the geological time interval,
a modeling module configured to provide an Earth system model with a plurality of input sets of modeling parameters, each input set of modeling parameters comprising the at least one paleo-digital elevation model, an orbital configuration of the Earth, and an atmospheric carbon dioxide concentration value, the atmospheric carbon dioxide concentration value, or the paleo-digital elevation model being distinct to one input set of modeling parameters to another one, and, for each input set of modeling parameters, obtain an output set of paleoenvironmental parameters as a function of spatial coordinates of the region of interest,
a determining module configured to determine a plurality of representative paleoenvironmental parameters for each carbonate reference location from the plurality of output sets of paleoenvironmental parameters,
a grouping module configured to group at least a part of the carbonate reference locations into at least one group of carbonate reference locations based on similarities between at least a part of the representative paleoenvironmental parameters of said carbonate reference locations, said representative paleoenvironmental parameters being specific of a carbonate factory which produced the marine carbonate sediments during the geological time interval, and
a computing module configured to compute a susceptibility of occurrence of a carbonate factory as a function of spatial coordinates of the region of interest using spatial distributions of the part of the representative paleoenvironmental parameters.

19. A computer program product comprising software instructions which, when the program is executed by a computer, cause the computer to carry out the method according to claim 1.

20. The method according to claim 1, wherein identifying the at least one area of interest from the region of interest is for exploration of water or non-renewable energy resources.

21. The system according to claim 18, wherein identifying the at least one area of interest from the region of interest is for exploration of water or non-renewable energy resources.
